(19) United States
(12) Patent Application Publication
(10) Pub. No.: US 2007/0216019 A1
(43) Pub. Date: Sep. 20, 2007

(54) LAMINATED IC PACKAGING SUBSTRATE AND INTER-CONNECTOR STRUCTURE THEREOF

(76) Inventor: Shih-Ping Hsu, Taoyuan County (TW)

Correspondence Address: NORTH AMERICA INTELLECTUAL PROPERTY CORPORATION, P.O. BOX 506, MERRIFIELD, VA, 22116, US

(21) Appl. No.: 11/616,299

(22) Filed: Dec. 27, 2006

(30) Foreign Application Priority Data
Mar. 17, 2006 (TW) 095109331

(51) Int. Cl. H01L 23/12

(52) U.S. Cl. 257/700

(57) ABSTRACT

A laminated IC packaging substrate includes an intermediate connecting layer having a plurality of through holes. Each of the through holes is filled with solder material protruding from a top surface and/or a bottom surface of the intermediate connecting layer. A first circuit board having thereon a first wiring pattern is adhered to the top surface of the intermediate connecting layer using a first adhesive layer. A second circuit board having thereon a second wiring pattern is adhered to the bottom surface of the intermediate connecting layer using a second adhesive layer.

### BACKGROUND OF THE INVENTION

1. Field of the Invention

The present invention relates to a packaging substrate structure and, more particularly, to a laminated IC packaging substrate and inter-connector structure thereof, and manufacture method thereof.

2. Description of the Prior Art

As the functionality and performance of network systems, high-end servers, and mobile communication devices improves, the demand for high-performance, high pin count packages is increasing. This increasing demand requires new technologies, which incorporate high pin count and also delivers performance via impedance control, low crosstalk, DC/AC resistance, and low VG impedance.

Sophisticated inter-connect technology has become essential for meeting these needs by improving the density and reliability of the substrates for LSI package and module boards. While high-density packages such as flip-chip, BGA and PBGA devices permit very high input-output (I/O) counts, the resulting close dimensions introduce substantial yield and cost challenges.

Please refer to FIG. 1. FIG. 1 is a schematic, cross-sectional diagram illustrating a conventional semiconductor package 10. As shown in FIG. 1, the semiconductor package 10 includes an IC packaging substrate 12 having a top surface 14 and bottom surface 16. A chip or die 18 is bonded to the top surface 14 of the IC packaging substrate 12 by mounting the solder bumps 22 on the corresponding solder pads 15.

Typically, the gap between the chip 18 and the IC packaging substrate 12 is filled with underfill glue 24 to isolate and protect the internal part from being contamination, and after cured, to counteract the stress at the bonding interface of the solder bump 22. The underfill glue 24 also reinforces the bonding between the IC packaging substrate 12 and the chip 18. A plurality of solder ball pads 46 and corresponding solder balls 48 are provided on the bottom surface 16 of the IC packaging substrate 12 for connecting with a printed circuit board.

Conventionally, a high-density IC packaging substrate is fabricated by so-called build-up layer methods. For example, a core substrate 13 is provided. The core substrate 13 has thereon completed upper circuit layers 131 and lower circuit layers 132. The upper and lower circuit layers are electrically connected via plated through holes (PTH) 133. Build-up layer process is formed by a laminating method. Dielectric layers are laminated onto the top surface and bottom surface of the core substrate 13. After thermally hardening the dielectric layers, a plurality of via holes are formed in the dielectric layers by laser drilling on the dielectric layer to expose the contact pads of circuit layers. Subsequently, a conductive seed layer is formed over the surface of the dielectric layer and via holes. A photolithography process is then performed to form patterned photo-resist layer on the conductive seed layer. The patterned photo-resist layer has open area defining circuit pattern. Thereafter, electroplating process is carried out to plate metal into the open area in the photo-resist layer to form build-up circuit layer. Lastly, the photo-resist layer and the exposed conductive seed layer under photo-resist layer are removed. The above-described process is also referred to as Semi-Additive Process (SAP).

However, the above-described prior art has several shortcomings. First, in order to electrically connect the upper circuit layers 131 and lower circuit layers 132 of the IC packaging substrate, it is required to fabricate the plurality of plating through holes 133 in the core substrate 13. Each plating through hole 133 is connected with a laterally extending pad for landing a conductive blind via in the dielectric layers. The laterally extending pad occupies a relatively large surface area of the IC packaging substrate, and becomes an obstacle to further improvement of ultra fine line patterning and reduction of fine pitches. Second, the prior art SAP method cannot ensure the reliability in each build-up circuit layer. These shortcomings cause reduced reliability issue of the package substrate and the risk of massive scrap.

### SUMMARY OF THE INVENTION

It is one object of the present invention to provide a laminated IC packaging substrate and connector thereof, in order to solve the above-mentioned problems. The present invention can provide higher circuit density and reliability that facilitates very fine line processes.

It is another object of the present invention to provide a cheaper, faster, more efficient and more reliable method for fabricating a laminated IC packaging substrate. The intermediate connecting layer and the laminating circuit boards can be fabricated in advance and tested prior to the lamination process. After each connecting layer and circuit board passes the reliability test, the lamination process is carried out to form a laminated IC packaging substrate. Thus, the method is flexible and time and cost saving.

According to the claimed invention, an intermediate connecting layer for integrated circuit (IC) packaging substrate is disclosed. The intermediate connecting layer comprises: a material substrate having a top surface and a bottom surface; a plurality of through holes in the material substrate communicating the top surface and the bottom surface; and an electroplated solder plug filling the through holes. The electroplated solder plug protrudes from both the top surface and the bottom surface of the intermediate connecting layer. The electroplated solder plug may protrudes from either the top surface or the bottom surface of the intermediate connecting layer.

From one aspect of this invention, a laminated IC packaging substrate comprises an intermediate connecting layer having a plurality of through holes. Each of the through holes is filled with solder material protruding from a top surface and/or a bottom surface of the intermediate connecting layer. A first circuit board having thereon a first wiring pattern is adhered to the top surface of the intermediate connecting layer using a first adhesive layer. A second circuit board having thereon a second wiring pattern is adhered to the bottom surface of the intermediate connecting layer using a second adhesive layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIG. 1 is a schematic, cross-sectional diagram illustrating a conventional semiconductor package according to the prior art;

FIG. 2 is a schematic, cross-sectional diagram showing a four-layer IC packaging substrate in accordance with the first preferred embodiment of this invention;

FIGS. 3-6 are schematic, cross-sectional diagrams showing different types of intermediate connecting layer of an IC packaging substrates in accordance with this invention; and

FIG. 7 is a schematic, cross-sectional diagram showing a six-layer IC packaging substrate in accordance with the second preferred embodiment of this invention.

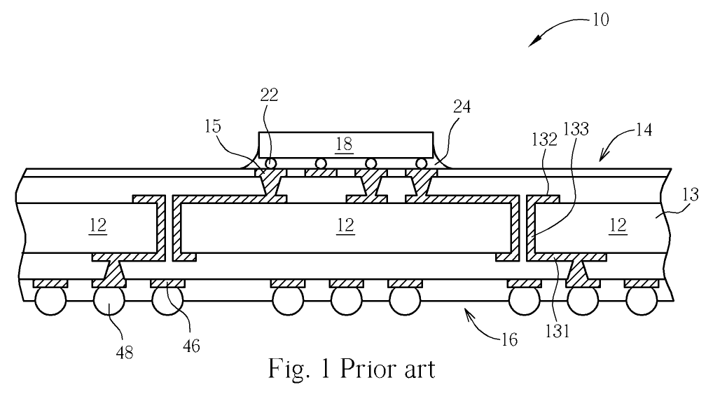

### DETAILED DESCRIPTION

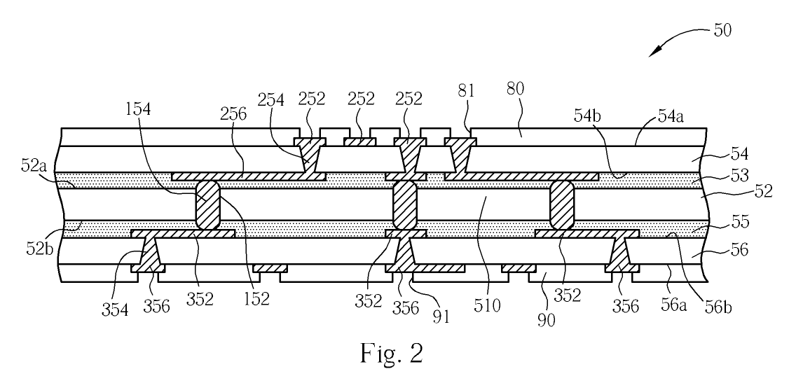

In describing the preferred embodiments of the present invention, reference will be made herein to FIGS. 2-7 of the drawings. Features of the invention are not drawn to scale in the drawings. For the sake of simplicity, hereinafter, an IC packaging substrate with four layers of circuit pattern and an IC packaging substrate with six layers of circuit pattern will be referred to as a four-layer IC packaging substrate and a six-layer IC packaging substrate, respectively.

FIG.2 is a schematic, cross-sectional diagram showing a four-layer IC packaging substrate 50 in accordance with the first preferred embodiment of this invention. As shown in FIG. 2, the four-layer IC packaging substrate 50 of this invention includes an intermediate connecting layer 52, a first circuit board 54, and a second circuit board 56. The intermediate connecting layer is made of a substrate 510 having a top surface 52a and a bottom surface 52b. Circuits are formed on upper and lower surfaces of each of the first circuit board 54 and second circuit board 56. According to this invention, the intermediate connecting layer 52 is used to electrically connect the circuits on the first circuit board 54 and second circuit board 56.

The first circuit board 54 and the second circuit board 56 are adhered to the top surface 52a and the bottom surface 52b of the intermediate connecting layer 52 with an adhesive layers 53 and 55, respectively. The adhesive layers 53 and 55 may comprise liquid organic resins, FR-5, Prepreg, Ajinomoto build-up film (ABF) and the like, which can be applied to the surfaces of the intermediate connecting layer 52 or surfaces of the first or second circuit boards. The above-described laminated IC packaging substrate made by laminating upper and lower circuit boards with adhesive layer comprising electroplated solder plug materials connecting the upper and lower circuit boards is the distinct feature of this invention, which is novel in this industry. Compared with the prior art, it is advantageous to use the present invention laminated IC packaging substrate because the intermediate connecting layer 52, the first circuit board 54 and the second circuit board 54 are fabricated, quality inspected and tested separately, thereafter the intermediate connecting layer 52, the first circuit board 54 and the second circuit board 54 are laminated together to form the laminated IC packaging substrate of this invention. By doing this, the fabrication process becomes more flexible, the throughput is improved and the product quality and yield are increased.

The above-described first and second circuit board 54 and 56 may be formed by starting with a double-sided copper clad laminate (CCL). The double-sided CCL is processed through drilling, chemical copper deposition, copper plating, and resist patterning, circuit etching and resist stripping to form the circuit board 54 and 56, each of which has two layers of circuit pattern thereon. The first and second circuit board 54 and 56 and the intermediate connecting layer 52 are then laminated using a circuit board laminating process to form the multi-layer IC packaging substrate.

The first circuit board 54 has a top surface 54a and a bottom surface 54b. After the circuit board laminating process, the top surface 54a is covered with an insulating protection layer 80, typically a solder mask. A plurality of openings 81 are formed in the insulating protection layer 80 to reveal the connecting pads 252 of the first circuit board 54. Chip or die (not shown) is mounted on connecting pads 252 distributed on the top surface 54a of the first circuit board 54 utilizing ball grid array (BGA) technology.

The second circuit board 56 has a top surface 56b and a bottom surface 56a. Likewise, after the circuit board laminating process, the bottom surface 56a is covered with an insulating protection layer 90. A plurality of openings 91 are formed in the insulating protection layer 90 to reveal the connecting or bonding pads 356 of the second circuit board 56. An external circuit device such as a printed circuit board (not shown) is mounted on connecting or bonding pads 356 distributed on the bottom surface 56a of the second circuit board 56.

According to the present invention, the intermediate connecting layer 52 is made of a material substrate 510. A plurality of through holes 152 are form in the material substrate 510. Each of the through holes 152 is filled with solder plug 154. According to the preferred embodiments, the solder plug 154 may be formed using electroplating methods. Preferably, the solder plug 154 comprises materials having relatively higher melting temperature including but not limited to, for example, Sn, Ag, Cu, Bi or any combination or alloy thereof. After electroplating, when the aforesaid circuit board laminating process is performed to form the laminated IC packaging substrate, a reflow process can be carried out to reflow the solder plug 154.

The material substrate 510 may be made of photosensitive organic resins or non-photosensitive organic resins. According to the preferred embodiment, the material substrate 510 may be made of materials selected form the group consisting of Ajinomoto Build-up Film (ABF), Poly(phenylene ether) (PPE), Poly(tetra-fluoroethylene) (PTFE), FR-4, FR-5, Bismaleimide Triazine (BT), Liquid Crystal Polymer (LCP), Benzocyclo-buthene (BCB), Polyimide (PI), and Aramide, but not limited thereto.

The plurality of connecting pads 252 on the top surface 54a of the first circuit board 54 are connected with corresponding bumps of a chip or die (not shown). The connecting pads 252 are electrically connected with the circuit pattern 256 on the bottom surface 54b of the first circuit board 54 via the conductive blind holes 254. A circuit pattern 352 is formed on the top surface 56b of the second circuit board 56. The solder plug 154 electrically connects the circuit pattern 256 of the first circuit board 54 with the circuit pattern 352 of the second circuit board 56. The circuit pattern 352 is then electrically connected with the connecting pads 356 on the bottom surface 56a via the conductive blind holes 354. To connect the second circuit board 56 with a printed circuit board, solder balls (not shown) are formed on the respective connecting pads 356.

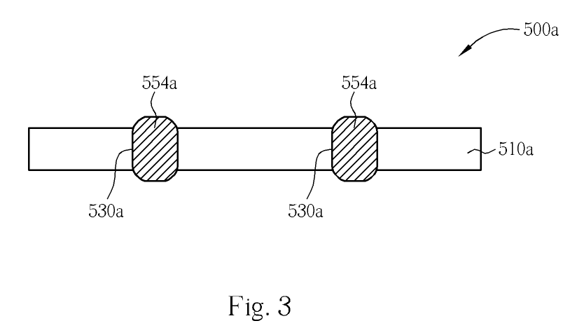

Please refer to FIGS. 3-6. FIGS. 3-6 are schematic, cross-sectional diagrams showing different types of intermediate connecting layer of an IC packaging substrates in accordance with this invention. As shown in FIG. 3, the intermediate connecting layer 500a comprises a material substrate 510a. The material substrate 510a may be made of materials selected form the group consisting of Ajinomoto Build-up Film (ABF), Poly(phenylene ether) (PPE), Poly(tetra-fluoroethylene) (PTFE), FR-4, FR-5, Bismaleimide Triazine (BT), Liquid Crystal Polymer (LCP), Benzocyclo-buthene (BCB), Poly-imide (PI), and Aramide, but not limited thereto. A plurality of through holes 530a are formed in the substrate 510a. The through holes 530a may be made by using lithographic processes, mechanical drilling or laser drilling methods.

A layer of conductive seed material such as electroless copper can be formed on sidewall of the through hole 530a and on the surface of the material substrate 510a. By using the conductive seed material as a current conductive path, the through hole 530a can be filled with the solder plug 554a during an electroplating process. Preferably, the solder plug 554a comprises materials having relatively higher melting temperature including but not limited to, for example, Sn, Ag, Cu, Bi or any combination or alloy thereof.

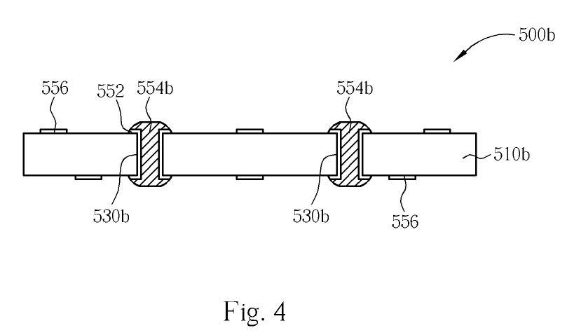

As shown in FIG. 4, the intermediate connecting layer 500b comprises a material substrate 510b. The material substrate 510b may be made of materials selected form the group consisting of Ajinomoto Build-up Film (ABF), Poly(phenylene ether) (PPE), Poly(tetrafluoroethylene) (PTFE), FR-4, FR-5, Bismaleimide Triazine (BT), Liquid Crystal Polymer (LCP), Benzocyclo-buthene (BCB), Poly-imide (PI), and Aramide, but not limited thereto. A plurality of through holes 530b are formed in the material substrate 510b. The through holes 530b may be made by using lithographic processes, mechanical drilling or laser drilling methods.

A layer of conductive seed material such as electroless copper can be formed on sidewall of the through hole 530b and on the surface of the material substrate 510b. By using the conductive seed material as a current conductive path, a circuit pattern layer 556 and a plated through hole 552 can be formed on the top and bottom surfaces of the material substrate 510b using a circuit patterning process. The plated through hole 552 can be filled with the solder plug 554b during a subsequent electroplating process. Preferably, the solder plug 554b comprises materials having relatively higher melting temperature including but not limited to, for example, Sn, Ag, Cu, Bi or any combination or alloy thereof.

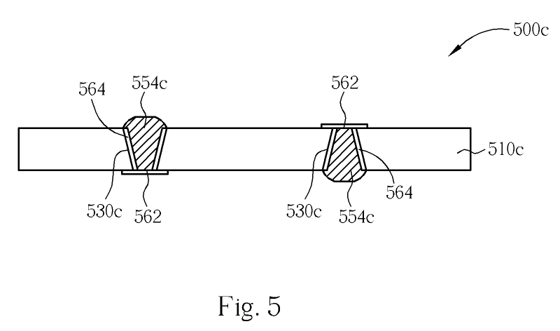

As shown in FIG. 5, the intermediate connecting layer 500c comprises a material substrate 510c. The substrate 510c may be made of materials selected form the group consisting of Ajinomoto Build-up Film (ABF), Poly(phenylene ether) (PPE), Poly(tetra-fluoroethylene) (PTFE), FR-4, FR-5, Bismaleimide Triazine (BT), Liquid Crystal Polymer (LCP), Benzocyclo-buthene (BCB), Poly-imide (PI), and Aramide, but not limited thereto. A plurality of through holes 530c are formed in the material substrate 510c. The through holes 530c is made by using laser drilling methods. Using conventional circuit patterning methods, connecting metal pads 562 are formed at one end of the corresponding through holes 530c.

A layer of conductive seed material such as electroless copper 564 can be formed on sidewall of the through hole 530c. By using the conductive seed material as a current conductive path, the through hole 530c can be filled with the solder plug 554c during an electroplating process. Since one end of each through hole 530c is sealed by a connecting metal pad 562, the solder plug 554c will only protrude out from the other end of each through hole 530c. Preferably, the solder plug 554c comprises materials having relatively higher melting temperature including but not limited to, for example, Sn, Ag, Cu, Bi or any combination or alloy thereof. After plating, when the aforesaid circuit board laminating process is performed to form the laminated IC packaging substrate, a reflow process can be carried out to reflow the solder plug 554c.

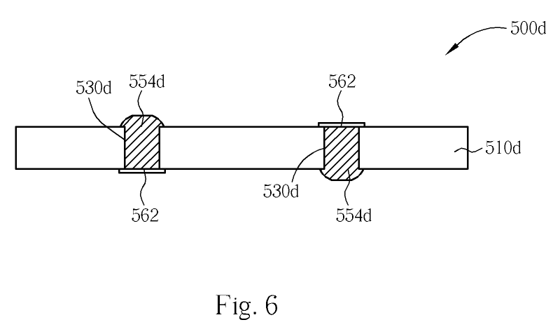

As shown in FIG. 6, the intermediate connecting layer 500d comprises a material substrate 510d. The material substrate 510d may be made of materials selected form the group consisting of Ajinomoto Build-up Film (ABF), Poly(phenylene ether) (PPE), Poly(tetra-fluoroethylene) (PTFE), FR-4, FR-5, Bismaleimide Triazine (BT), Liquid Crystal Polymer (LCP), Benzocyclo-buthene (BCB), Poly-imide (PI), and Aramide, but not limited thereto. A plurality of through holes 530d are formed in the substrate 510d.

The major difference between the embodiments depicted in FIG. 5 and FIG. 6 is that the through hole 530d in FIG. 6 drilled by using mechanical drilling methods. Further, there is no metal seed layer formed on sidewall of the through hole 530d. Using conventional circuit patterning methods, connecting metal pads 562 are formed at one end of the corresponding mechanically drilled through holes 530d. The through hole 530d is then filled with the solder plug 554d during a subsequent electroplating process.

The solder plug 554d protrudes from one surface of the substrate 510d. Preferably, the solder plug 554d comprises materials having relatively higher melting temperature including but not limited to, for example, Sn, Ag, Cu, Bi or any combination or alloy thereof.

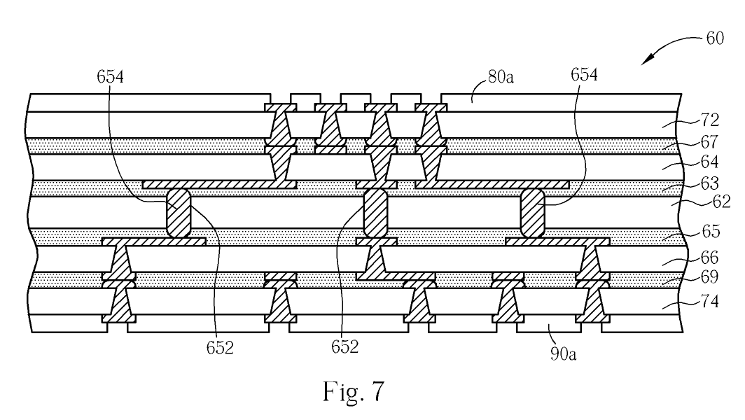

Please refer to FIG. 7. FIG. 7 is a schematic, cross-sectional diagram showing a six-layer IC packaging substrate 60 in accordance with the second preferred embodiment of this invention. As shown in FIG. 7, the present invention six-layer IC packaging substrate 60 comprises an intermediate connecting layer 62, a first circuit board 64, a second circuit board 66, a third circuit board 72 and a fourth circuit board 74. The intermediate connecting layer 62 may be selected from any substrate depicted in FIGS. 3-6.

According to this invention, the intermediate connecting layer 62 is used to electrically connect the circuits on the first circuit board 64 and second circuit board 66. The first circuit board 64 and the second circuit board 66 are adhered to the top surface and the bottom surface of the intermediate connecting layer 62 with adhesive layers 63 and 65, respectively.

The third circuit board 72 and the fourth circuit board 74 are adhered to the first circuit board 64 and the second circuit board 66 with adhesive layers 67 and 69, respectively. The adhesive layers may comprise liquid organic resins, FR-5, Prepreg, Ajinomoto build-up film (ABF) and the like, which can be applied to the surfaces of the intermediate connecting layer 62 or surfaces of the circuit boards.

An insulating protection layer 80a and an insulating protection layer 90a cover the other sides of the third circuit board 72 and the fourth circuit board 74 to protect the six-layer IC packaging substrate 60 from scratching or moisture. The insulating protection layers 80a and 90a both have a plurality of openings for revealing the connecting pads, through which the six-layer IC packaging substrate 60 can communicate with an external electric device.

According to this invention, a plurality of through holes 652 are provided in the intermediate connecting layer 62. Each of the through holes 652 is filled with solder plug 654. According to the second preferred embodiment, the solder plug 654 is formed using electroplating process.

Preferably, the solder plug 654 comprises materials having relatively higher melting temperature including but not limited to, for example, Sn, Ag, Cu, Bi or any combination or alloy thereof. After plating, when the aforesaid circuit board laminating process is performed to form the laminated IC packaging substrate, a reflow process can be carried out to reflow the solder plug 654.

Alternatively, the third circuit board 72 and the fourth circuit board 74 can be replaced with any substrate depicted in FIGS. 3-6. Before attaching to the intermediate connecting layer 65, a type of substrate selected from FIGS. 3-6 can be laminated on the first circuit board 64, and a type of substrate selected from FIGS. 3-6 can be laminated on the second circuit board 66.

Chip or die (not shown) is mounted on connecting pads distributed on the top surface of the third circuit board 72 utilizing ball grid array (BGA) technology. An external circuit device such as a printed circuit board (not shown) is mounted on connecting pads distributed on the bottom surface of the fourth circuit board 74.

To sum up, the present invention has the following advantages. First, the present invention is superior than the prior art packaging substrate fabricated using traditional semi-additive processes because it is cheaper, faster, more efficient and more reliable.

The intermediate connecting layer and the laminating circuit boards can be fabricated in advance and tested prior to the lamination process. After each connecting layer and circuit board passes the reliability test, the lamination process is carried out to form a laminated IC packaging substrate. Thus, the method is flexible and time saving.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An intermediate connecting layer for integrated circuit (IC) packaging substrate, comprising:
a material substrate having a top surface and a bottom surface;
a plurality of through holes in the material substrate communicating the top surface and the bottom surface; and
an electroplated solder plug filling the through holes.

2. The intermediate connecting layer for IC packaging substrate according to claim 1 wherein at least one patterned circuit layer is formed on top or bottom surface of the material substrate.

3. The intermediate connecting layer for IC packaging substrate according to claim 1 wherein the electroplated solder plug comprises Sn, Ag, Cu, Bi or any combination or alloy thereof.

4. The intermediate connecting layer for IC packaging substrate according to claim 1 wherein the material substrate is made of photosensitive organic resins or non-photosensitive organic resins.

5. The intermediate connecting layer for IC packaging substrate according to claim 4 wherein the material substrate is made of materials selected form the group consisting of Ajinomoto Build-up Film (ABF), Poly(phenylene ether) (PPE), Poly(tetra-fluoroethylene) (PTFE), FR-4, FR-5, Bismaleimide Triazine (BT), Liquid Crystal Polymer (LCP), Benzocyclo-buthene (BCB), Poly-imide (PI), and Aramide.

6. The intermediate connecting layer for IC packaging substrate according to claim 1 wherein the through holes are formed using laser drilling method.

7. The intermediate connecting layer for IC packaging substrate according to claim 1 wherein the through holes are formed using mechanical drilling method.

8. The intermediate connecting layer for IC packaging substrate according to claim 1 wherein at least one metal pad is formed on top or bottom surface of the material substrate to seal one end of one of the through holes.

9. The intermediate connecting layer for IC packaging substrate according to claim 1 wherein an electroplating or electroless plating metal layer is formed on sidewall of the through holes.

10. The intermediate connecting layer for IC packaging substrate according to claim 1 wherein the electroplated solder plug protrudes from the top surface or the bottom surface of the intermediate connecting layer.

11. A laminated IC packaging substrate, comprising:
an intermediate connecting layer having thereon a plurality of through holes and an electroplated solder plug filling each of the plurality of through holes;
a first circuit board having thereon a first wiring pattern is adhered to the top surface of the intermediate connecting layer using a first adhesive layer; and
a second circuit board having thereon a second wiring pattern is adhered to the bottom surface of the intermediate connecting layer using a second adhesive layer.

12. The laminated IC packaging substrate according to claim 11 wherein the electroplated solder plug protrudes from both the top surface or the bottom surface of the intermediate connecting layer.

13. The laminated IC packaging substrate according to claim 11 wherein the electroplated solder plug is reflowed plating solder material.

14. The laminated IC packaging substrate according to claim 11 wherein the electroplated solder plug comprises Sn, Ag, Cu, Bi or any combination or alloy thereof.

15. The laminated IC packaging substrate according to claim 11 wherein the intermediate connecting layer is made of photosensitive organic resins or non-photosensitive organic resins.

16. The laminated IC packaging substrate according to claim 11 wherein the first and second adhesive layers are made of organic resins.

17. The laminated IC packaging substrate according to claim 11 wherein the first wiring pattern comprises a first connecting pad connecting with the electroplated solder plug.

18. The laminated IC packaging substrate according to claim 11 wherein the second wiring pattern comprises a second connecting pad connecting with the electroplated solder plug.

19. The laminated IC packaging substrate according to claim 11 wherein the first circuit board or the second circuit board is adhered to another connecting layer before attaching to the intermediate connecting layer.
